(19) United States
(12) Patent Application Publication
(10) Pub. No.: US 2026/0184503 A1
(43) Pub. Date: Jul. 2, 2026

(54) TRANSFER ROBOT AND CONTAINER STORAGE FACILITY INCLUDING THE SAME

(71) Applicant: SEMES CO., LTD., Cheonan-si (KR)

(72) Inventors: Eun Sang YOON, Gyeonggi-do (KR); Jae Min CHAE, Seoul (KR); Jae Il YU, Gyeonggi-do (KR)

(73) Assignee: SEMES CO., LTD., Cheonan-si (KR)

(21) Appl. No.: 19/367,381

(22) Filed: Oct. 23, 2025

(30) Foreign Application Priority Data
Dec. 27, 2024 (KR) 10-2024-0198131

(51) Int. Cl. B65G 1/04; B25J 5/02

(52) U.S. Cl. CPC B65G 1/0407; B25J 5/02; B65G 2201/0235

(57) ABSTRACT

There is provided a transfer robot capable of picking up different types of containers. The transfer robot comprising, a base, a first hand installed on the base and configured to pick up a first-type container having a first width, a second hand installed on the base and configured to pick up a second-type container having a second width different from the first width, the second hand including a passage through which the first hand passes, a first actuator configured to adjust a position in an up-and-down direction between the first hand and the second hand, and a controller configured to control the first actuator, wherein, in a case where the first hand picks up the first-type container, the controller controls the first actuator to position the first hand higher than the second hand relative to the base.

### CROSS-REFERENCE TO RELATED APPLICATION

This application claims priority from Korean Patent Application No. 10-2024-0198131 filed on Dec. 27, 2024 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a transfer robot and a container storage facility including the same.

### 2. Description of the Related Art

A wafer subjected to a semiconductor manufacturing process in a semiconductor fabrication factory (FAB) is stored in a container and transferred. In addition, a container storage facility may be installed in the FAB. The container storage facility may store containers storing wafers undergoing a manufacturing process, containers storing wafers having completed the manufacturing process, and the like. The container storage facility includes a shelf for storing containers and a transfer robot for transferring containers to the shelf. The container storage facility may be, for example, a stocker.

Meanwhile, various types of containers may be used for storing wafers, and demand is increasing for container storage facilities capable of storing various types of containers.

However, since the shape of containers may vary depending on their type, the shape of the shelf for storing the containers and the shape of the hand of the transfer robot may also vary. Accordingly, there is an increasing need for developing a container storage facility capable of accommodating various types of containers.

### SUMMARY

An objective of the present disclosure is to provide a transfer robot capable of picking up different types of containers.

Another objective of the present disclosure is to provide a container storage facility capable of storing and transferring different types of containers.

The objectives of the present disclosure are not limited to those mentioned above, and other objectives not explicitly stated will be clearly understood by those skilled in the art based on the following description.

According to an aspect of the present disclosure, a transfer robot comprising, a base, a first hand installed on the base and configured to pick up a first-type container having a first width, a second hand installed on the base and configured to pick up a second-type container having a second width different from the first width, the second hand including a passage through which the first hand passes, a first actuator configured to adjust a position in an up-and-down direction between the first hand and the second hand, and a controller configured to control the first actuator, wherein, in a case where the first hand picks up the first-type container, the controller controls the first actuator to position the first hand higher than the second hand relative to the base.

According to another aspect of the present disclosure, a container storage facility comprising, a shelf configured to selectively store a first-type container having a first width or a second-type container having a second width, different from the first width, and a crane configured to transfer the first-type container and the second-type container to the shelf and comprising a body and a transfer robot configured to move up and down relative to the body, wherein the transfer robot comprises, a base, a first hand installed on the base and configured to pick up the first-type container from the shelf, a second hand installed on the base and configured to pick up the second-type container from the shelf, the second hand including a passage through which the first hand passes, and a first actuator configured to adjust a position in an up-and-down direction between the first hand and the second hand.

According to another aspect of the present disclosure, a container storage facility comprising, a shelf configured to selectively store a first-type container having a first width or a second-type container having a second width, smaller than the first width, the shelf comprising a first support configured to support the first-type container and a second support installed below the first support and configured to support the second-type container, and a crane configured to transfer the first-type container and the second-type container to the shelf, and comprising a body and a transfer robot configured to move up and down relative to the body, wherein the transfer robot comprises, a base, a first hand installed on the base and configured to pick up the first-type container from the shelf, a second hand installed on the base and configured to pick up the second-type container from the shelf, the second hand including a passage through which the first hand passes, an actuator connected to the first hand and penetrating the second hand, the actuator being configured to move the first hand in the up-and-down direction relative to the base, and a controller configured to control the actuator, in a case where the first hand picks up the first-type container, the controller controls the actuator to position the first hand higher than the second hand relative to the base, and in a case where the second hand picks up the second-type container, the controller controls the actuator to position the first hand lower than the second hand relative to the base.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing exemplary embodiments thereof in detail with reference to the attached drawings, in which:

FIG. 1 is a diagram illustrating a container storage facility according to some embodiments of the present disclosure.

FIG. 2 is a plan view illustrating the container storage facility of FIG. 1.

FIG. 3 is a perspective view illustrating a shelf of FIG. 1.

FIG. 4 is a perspective view illustrating the transfer robot of FIG. 1.

FIG. 5 is a side view illustrating the transfer robot of FIG. 1.

FIG. 6 is a plan view illustrating the transfer robot of FIG. 1.

FIG. 7 is a conceptual diagram illustrating the transfer robot of FIG. 1.

FIG. 8 is a plan view illustrating a second hand of FIG. 4.

FIG. 9 is a perspective view illustrating a first actuator of FIG. 4.

FIG. 10 is a perspective view illustrating a second actuator of FIG. 4.

FIG. 11 is a flowchart for explaining an operation in which a transfer robot according to some embodiments of the present disclosure picks up a first-type container from a shelf.

FIGS. 12-15 are intermediate drawings for explaining the operation of FIG. 11.

FIG. 16 is a flowchart for explaining an operation in which the transfer robot according to some embodiments of the present disclosure picks up a second-type container from a shelf.

FIGS. 17-20 are intermediate drawings for explaining the operation of FIG. 16.

### DETAILED DESCRIPTION

In this specification, although terms such as first, second, and the like are used to describe various elements or components, it should be understood that the elements or components are not limited by such terms. These terms are merely used to distinguish one element or component from another element or component. Accordingly, a first element or component referred to below may also be a second element or component within the technical spirit of the present disclosure.

The terminology used in this specification is intended to describe embodiments, not to limit the present disclosure. In this specification, the singular form includes the plural form unless otherwise specifically mentioned in the context. The terms “comprises” and/or “comprising,” as used in this specification, do not exclude the possibility of one or more other elements being present or added in addition to the mentioned elements.

Unless otherwise defined, all terms (including technical and scientific terms) used in this specification may be understood in the sense commonly used by one of ordinary skill in the art to which the present disclosure pertains. In addition, terms defined in generally used dictionaries are not to be interpreted in an idealized or exaggerated sense unless expressly defined otherwise.

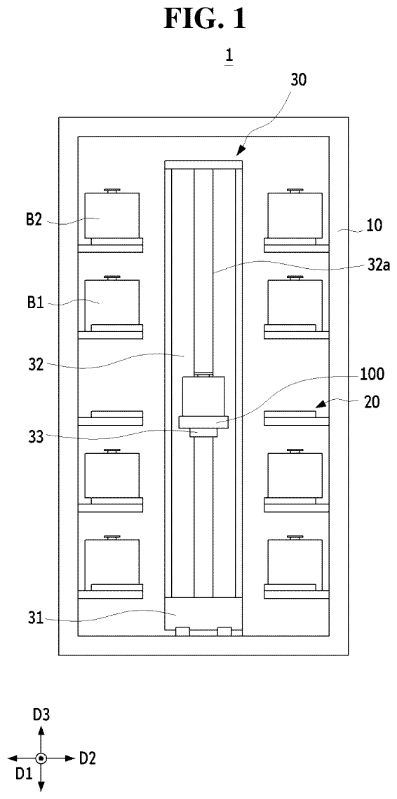

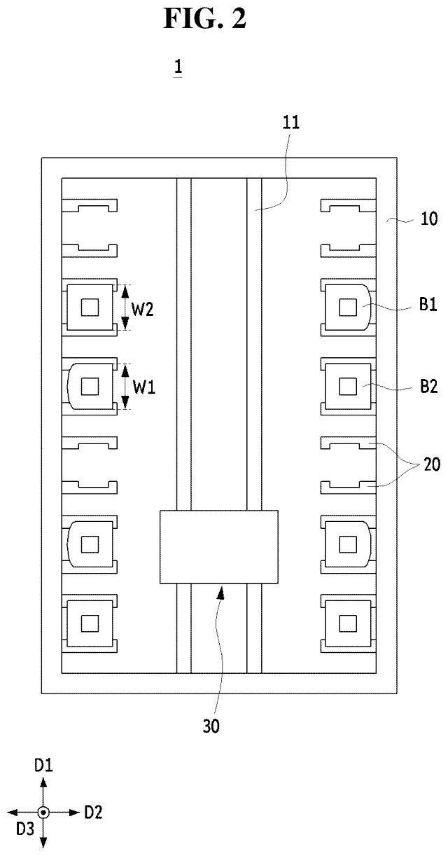

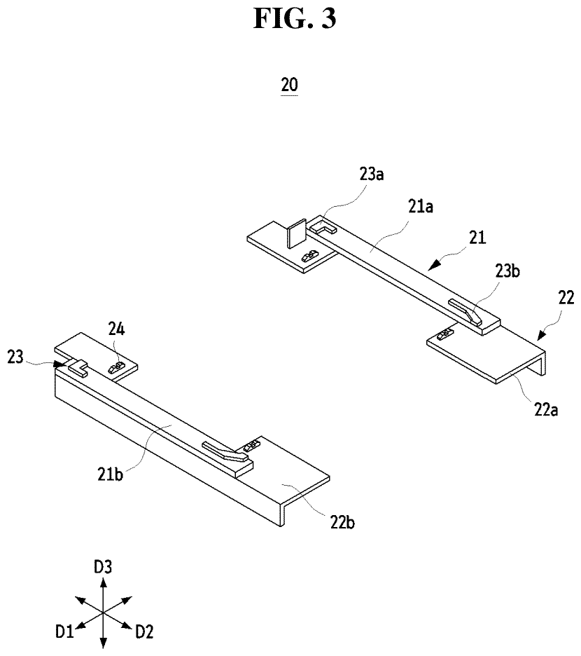

FIG. 1 is a diagram illustrating a container storage facility according to some embodiments of the present disclosure. FIG. 2 is a plan view illustrating the container storage facility of FIG. 1. FIG. 3 is a perspective view illustrating a shelf of FIG. 1.

Referring to FIGS. 1-3, a container storage facility 1 according to some embodiments of the present disclosure includes a frame 10, a plurality of shelves 20, and a crane 30.

The shelves 20 are installed in the frame 10. The frame 10 includes two long sidewalls parallel to each other and short sidewalls connecting the long sidewalls. The shelves 20 are installed on the long sidewalls of the frame 10. The shelves 20 may be arranged in a matrix form on the long sidewalls of the frame 10. The shelves 20 installed on one long sidewall of the frame 10 and the shelves 20 installed on the other long sidewall of the frame 10 may face each other.

A first direction D1 may be a direction in which the long sidewalls of the frame 10 extend. A second direction D2 may be a direction intersecting the first direction D1, and may be a direction in which the shelves 20 installed on different long sidewalls of the frame 10 face each other. A third direction D3 may be a direction intersecting the first and second directions D1 and D2, and may be a direction perpendicular to the bottom surface of the frame 10.

Each of the shelves 20 is configured to selectively store a first-type container B1 or a second-type container B2. Specifically, each of the shelves 20 stores one container at a time, and the container stored on each of the shelves 20 may be either the first-type container B1 or the second-type container B2. That is, each of the shelves 20 does not store the first-type container B1 and the second-type container B2 together.

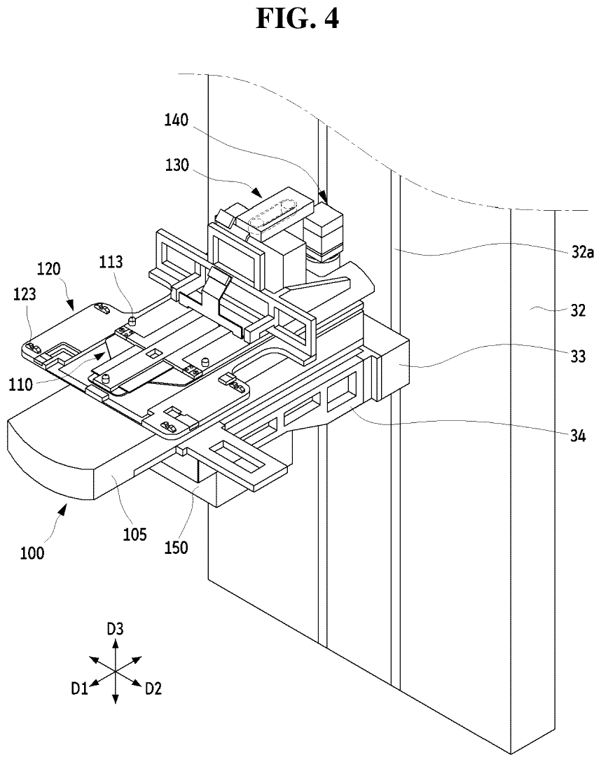

The first-type container B1 and the second-type container B2 may each be a container for storing wafers. The first-type container B1 and the second-type container B2 differ in shape and size. A width W1 of the first-type container B1 and a width W2 of the second-type container B2 are different from each other. For example, the width W1 of the first-type container B1 in the first direction D1 may be greater than the width W2 of the second-type container B2 in the first direction D1. A bottom plate of the first-type container B1 may be formed with a hole into which a position pin 113 of FIG. 4 to be described below is inserted. For example, the first-type container B1 may be, but is not limited to, a front opening unified pod (FOUP) or a front opening shipping box (FOSB), and the second-type container B2 may be, but is not limited to, a cassette.

Referring to FIG. 3, a shelf 20 includes a first support 21 and a second support 22. The first support 21 is configured to support a first-type container B1. The first support 21 includes a first portion 21a and a second portion 21b spaced apart from each other in the first direction D1. Since the first and second portions 21a and 21b supporting the first-type container B1 are spaced apart from each other, a first hand 110 of FIG. 4 to be described below may enter a space between the first and second portions 21a and 21b to pick up the first-type container B1.

The shelf 20 may further include a plurality of fixing blocks 23 installed on the first support 21. Some of the fixing blocks 23 are arranged on the first portion 21a of the first support 21, and other fixing blocks 23 are arranged on the second portion 21b of the first support 21. The fixing blocks 23 may fix the first-type container B1 seated on the first support 21. The fixing blocks 23 may contact the sidewalls of the first-type container B1.

The fixing blocks 23 may include a plurality of first fixing blocks 23a and a plurality of second fixing blocks 23b. The first fixing blocks 23a may fix a front portion of the first-type container B1. The front portion of the first-type container B1 is a portion where a door for wafer entry and exit is installed. The second fixing blocks 23b may fix a rear portion of the first-type container B1. A pair consisting of a first fixing block 23a and a second fixing block 23b may be installed on each of the first and second portions 21a and 21b of the first support 21.

The second support 22 may be installed below the first support 21. The second support 22 may be directly connected to the first support 21. The second support 22 is configured to support a second-type container B2. The second support 22 includes a first portion 22a and a second portion 22b spaced apart from each other in the first direction D1.

The first portion 22a of the second support 22 may be disposed below the first portion 21a of the first support 21. The second portion 22b of the second support 22 may be arranged below the second portion 21b of the first support 21. Since the first and second portions 22a and 22b supporting the second-type container B2 are spaced apart from each other, a second hand 120 of FIG. 4 to be described below may enter a space between the first and second portions 22a and 22b to pick up the second-type container B2.

The shelf 20 may further include a plurality of support blocks 24 installed on the second support 22. Some of the support blocks 24 are arranged on the first portion 22a of the second support 22, and other support blocks 24 are arranged on the second portion 22b of the second support 22. The support blocks 24 may fix the second-type container B2 seated on the second support 22. The support blocks 24 may contact a bottom plate of the second-type container B2 seated on the second support 22.

The crane 30 is configured to transfer the first-type container B1 or the second-type container B2 within the container storage facility 1. The container storage facility 1 may include a load port for loading/unloading the containers (B1 and B2) by an operator and/or an overhead hoist transport (OHT) port for loading/unloading the containers (B1 and B2) through an OHT. The crane 30 may transfer the containers (B1 and B2) between the shelves 20, between the shelves 20 and the load port, and between the shelves 20 and the OHT port.

The crane 30 is configured to travel within the container storage facility 1. The crane 30 may travel in the first direction D1 along the long sidewalls of the frame 10. A crane rail 11 may be installed on the bottom surface of the frame 10. The crane rail 11 is installed between the shelves 20. The crane rail 11 extends in the first direction D1 along the long sidewalls of the frame 10. The crane 30 may travel within the container storage facility 1 along the crane rail 11.

The crane 30 includes a moving device 31, a body 32, an elevator 33, and a transfer robot 100. The moving device 31 is configured to travel within the container storage facility 1 along the crane rail 11. The body 32 is installed on the moving device 31. The body 32 extends in the third direction D3.

The elevator 33 is installed on the body 32. The elevator 33 is configured to move up and down relative to the body 32. The elevator 33 may move along the body 32 in the third direction D3. A guide rail 32a extending in the third direction D3 may be installed on the body 32. The elevator 33 may move up and down relative to the body 32 along the guide rail 32a.

The transfer robot 100 is installed on the elevator 33. The transfer robot 100 is connected to the elevator 33. The transfer robot 100 may move up and down along the body 32 together with the elevator 33. The transfer robot 100 may move in the third direction D3 together with the elevator 33. The transfer robot 100 may move in the first direction D1 together with the moving device 31.

The transfer robot 100 is configured to pick up first-type containers B1 or second-type containers B2 from one of the shelves 20, the load port, or the OHT port. The transfer robot 100 is configured to deliver the picked-up first-type containers B1 or second-type containers B2 to one of the shelves 20, the load port, or the OHT port.

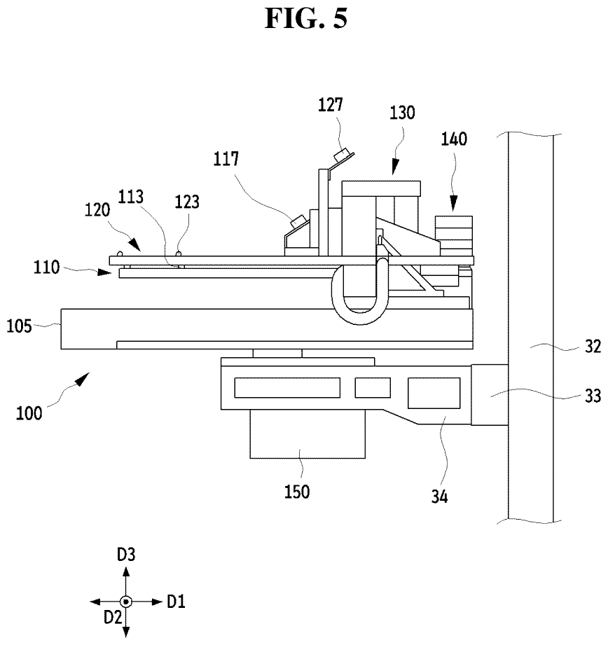

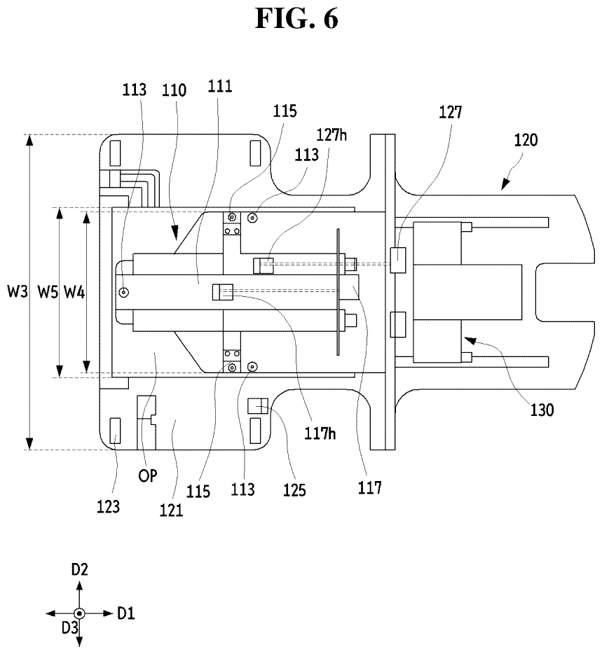

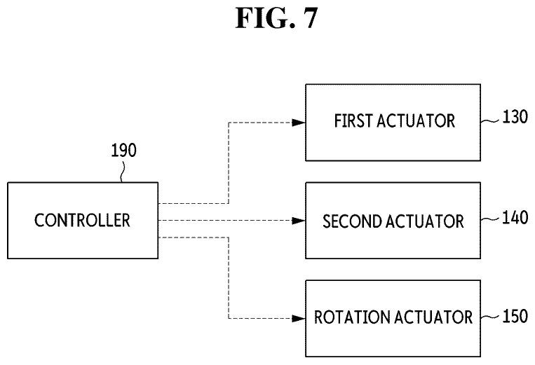

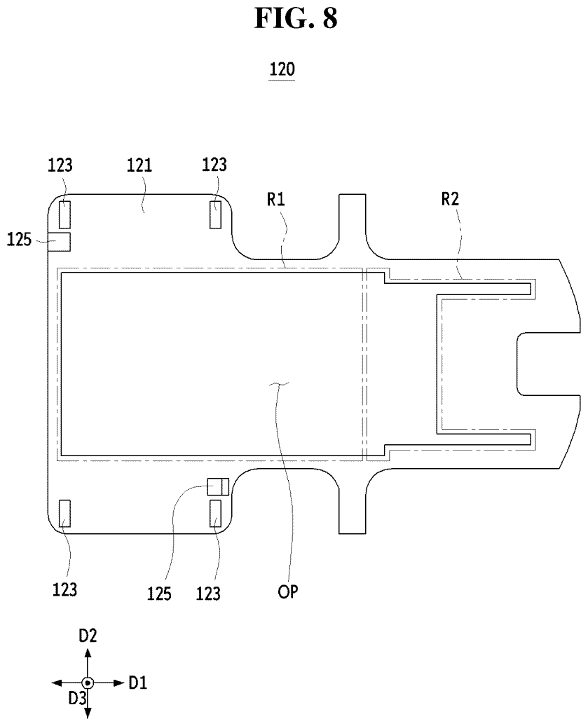

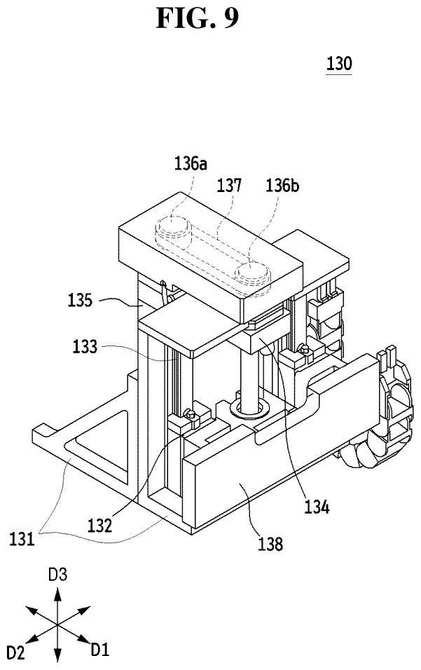

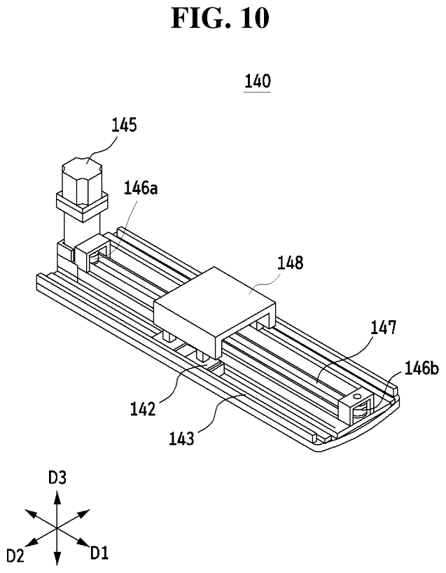

Hereinafter, the transfer robot 100 will be described in detail with reference to FIGS. 4-10. FIG. 4 is a perspective view illustrating the transfer robot of FIG. 1. FIG. 5 is a side view illustrating the transfer robot of FIG. 1. FIG. 6 is a plan view illustrating the transfer robot of FIG. 1. FIG. 7 is a conceptual diagram illustrating the transfer robot of FIG. 1. FIG. 8 is a plan view illustrating a second hand of FIG. 4. FIG. 9 is a perspective view illustrating a first actuator of FIG. 4. FIG. 10 is a perspective view illustrating a second actuator of FIG. 4.

Referring to FIGS. 4-10, the transfer robot 100 includes a base 105, a first hand 110, a second hand 120, a first actuator 130, a second actuator 140, a rotation actuator 150, and a controller 190. The controller 190 may control the operation of the first hand 110 or the second hand 120 by controlling at least one of the first actuator 130, the second actuator 140, and the rotation actuator 150.

The rotation actuator 150 is installed below the base 105. The rotation actuator 150 is connected to the elevator 33 by a connecting member 34. The rotation actuator 150 is configured to rotate the base 105 in a horizontal direction. The base 105 may perform a turning operation by the rotation actuator 150.

An up-and-down direction may be the third direction D3. A front-and-rear direction may be the first direction D1 or the second direction D2. A left-and-right direction may intersect the front-and-rear direction. The front-and-rear direction and the left-and-right direction may change as the base 105 performs the turning operation. Hereinafter, for convenience of description, the front-and-rear direction will be described as being the first direction D1 and the left-and-right direction will be described as being the second direction D2.

The first hand 110 is installed on the base 105. The first hand 110 is configured to pick up a first-type container B1. The first hand 110 is configured to support a first-type container B1.

The first hand 110 may be moved in the front-and-rear direction, i.e., the first direction D1, relative to the base 105 by the second actuator 140. That is, even when the base 105 does not move, the first hand 110 may be moved in the first direction D1 by the second actuator 140. The first hand 110 may perform a turning operation together with the base 105 via the rotation actuator 150.

In some embodiments, the first hand 110 may be moved in the up-and-down direction, i.e., the third direction D3, relative to the base 105 by the first actuator 130. That is, even when the base 105 does not move, the first hand 110 may be moved in the third direction D3 by the first actuator 130.

Referring to FIGS. 4-6, the first hand 110 includes a first plate 111, a plurality of position pins 113, a plurality of first load sensors 115, and a first diagonal sensor 117.

The position pins 113 are installed on the first plate 111. The position pins 113 are spaced apart from each other. Each of the position pins 113 may engage with a hole formed in the bottom plate of a first-type container B1. The first load sensors 115 are installed on the first plate 111 to determine whether a container is placed on the first plate 111.

The first diagonal sensor 117 is installed at a rear portion of the first plate 111 and faces the bottom surface of the first plate 111. A first hole 117h is formed in the bottom surface of the first plate 111, and a reflector is arranged inside the first hole 117h. The first diagonal sensor 117 provides light toward the reflector inside the first hole 117h. When a container is placed on the first plate 111, no light is reflected. When no container is placed on the first plate 111, light is reflected by the reflector inside the first hole 117h.

The second hand 120 is installed on the base 105. The second hand 120 is configured to pick up a second-type container B2. The second hand 120 is configured to support a second-type container B2. The second hand 120 may be moved in the first direction D1 relative to the base 105 by the second actuator 140. The second hand 120 may perform a turning operation together with the base 105 via the rotation actuator 150. In some embodiments, the second hand 120 may be moved in the third direction D3 relative to the base 105 by the first actuator 130.

Referring to FIGS. 4-6 and FIG. 8, the second hand 120 includes an opening OP. The opening OP of the second hand 120 is a passage through which the first hand 110 passes in the third direction D3. The first actuator 130 penetrates the second hand 120 in the third direction D3. The first actuator 130 penetrates the second hand 120 through the opening OP of the second hand 120.

The opening OP of the second hand 120 includes a first region R1 and a second region R2. The first region R1 of the opening OP is a region through which the first hand 110 passes the second hand 120. The second region R2 of the opening OP is a region through which the first actuator 130 penetrates the second hand 120. The first and second regions R1 and R2 are connected.

The second hand 120 includes a second plate 121, a plurality of support blocks 123, a plurality of second load sensors 125, and a second diagonal sensor 127. The second plate 121 includes the opening OP.

The support blocks 123 are installed on the second plate 121. The support blocks 123 are spaced apart from each other. Each of the support blocks 123 may support the bottom plate of a second-type container B2. The second load sensors 125 are installed on the second plate 121 to determine whether a container is placed on the second plate 121.

The second diagonal sensor 127 is installed at a rear portion of the second plate 121 and faces the bottom surface of the first plate 111. In some embodiments, a second hole 127h, different from the first hole 117h, may be formed in the bottom surface of the first plate 111. A reflector may be disposed inside the second hole 127h. The second diagonal sensor 127 provides light toward the reflector inside the second hole 127h. When a container is placed on the second plate 121, no light is reflected. When no container is placed on the second plate 121, light is reflected by the reflector inside the second hole 127h. In some embodiments, the second hole 127h may not be formed in the bottom surface of the first plate 111, and the second diagonal sensor 127 may share the first diagonal sensor 117 and the first hole 117h.

A width W3 of the second hand 120 in the left-and-right direction, i.e., the second direction D2, is greater than a width W4 of the first hand 110 in the second direction D2. A width W5 of the opening OP of the second hand 120 in the second direction D2 is greater than the width W4 of the first hand 110 in the second direction D2.

The first actuator 130 is installed on the base 105. The first actuator 130 is connected to the first and second hands 110 and 120. The first actuator 130 penetrates the second hand 120 and is connected to the second actuator 140. The first actuator 130 may be moved in the first direction D1 by the second actuator 140.

The first actuator 130 is configured to adjust a position in the third direction D3 between the first and second hands 110 and 120. The first actuator 130 may move at least one of the first and second hands 110 and 120 in the third direction D3 so that, relative to the base 105, the height of the first hand 110 becomes greater than the height of the second hand 120. The first actuator 130 may move at least one of the first and second hands 110 and 120 in the third direction D3 so that, relative to the base 105, the height of the first hand 110 becomes less than the height of the second hand 120. The first actuator 130 includes a moving part that moves in the third direction D3 and a fixed part that does not move in the third direction D3.

In some embodiments, the first actuator 130 is configured to move the first hand 110 in the third direction D3. In this case, the first hand 110 is fixed to the moving part of the first actuator 130, and the second hand 120 is fixed to the fixed part of the first actuator 130.

In some embodiments, the first actuator 130 is configured to move the second hand 120 in the third direction D3. In this case, the second hand 120 is fixed to the moving part of the first actuator 130, and the first hand 110 is fixed to the fixed part of the first actuator 130.

Referring to FIGS. 4-6 and FIG. 9, the first actuator 130 includes a frame 131, a ball screw 134, a motor 135, and a moving member 138.

The frame 131 is installed penetrating the second hand 120. The frame 131 may correspond to the fixed part of the first actuator 130. The ball screw 134 is installed on the frame 131. The ball screw 134 may extend in the third direction D3. The ball screw 134 may convert a rotational motion into a linear motion.

The motor 135 provides power to the ball screw 134. For example, a plurality of pulleys 136a and 136b and a belt 137 may be installed on the ball screw 134. The pulleys 136a and 136b are spaced apart from each other. The pulley 136a is connected to the motor 135 and may be rotated by the motor 135. The belt 137 connects the pulleys 136a and 136b. The pulley 136b may be rotated by receiving rotational force of the motor 135 from the pulley 136a through the belt 137. The pulley 136b is connected to the ball screw 134. The ball screw 134 may be driven in the third direction D3 by receiving power of the motor 135 through the pulleys 136a and 136b and the belt 137.

The moving member 138 is installed on the frame 131. The moving member 138 is connected to the ball screw 134. The moving member 138 may move in the third direction D3 as the ball screw 134 is driven in the third direction D3. The moving member 138 may correspond to the moving part of the first actuator 130.

When the first actuator 130 moves the first hand 110 in the third direction D3, the first hand 110 is fixed to the moving member 138, and the second hand 120 is fixed to the frame 131. Specifically, the first hand 110 is fixed to the front surface of the moving member 138 that is opposite to the rear surface of the moving member 138 to which the ball screw 134 is connected.

When the first actuator 130 moves the second hand 120 in the third direction D3, the second hand 120 is fixed to the front surface of the moving member 138, and the first hand 110 is fixed to the frame 131.

In some embodiments, the first actuator 130 may further include a slider 132 and a guide rail 133. The slider 132 is connected to the moving member 138. The moving member 138 is fixed to the slider 132. The guide rail 133 is installed on at least one side of the ball screw 134. The guide rail 133 extends in the third direction D3 to be in parallel to the ball screw 134. The slider 132 may move in the third direction D3 together with the moving member 138 along the guide rail 133. The slider 132 and the guide rail 133 may assist precise movement of the moving member 138.

The second actuator 140 is installed partly within and partly on the base 105. A portion of the second actuator 140 is positioned inside the base 105, and a remaining portion of the second actuator 140 is positioned on the base 105. The second actuator 140 may move the first and second hands 110 and 120 in the first direction D1. The first and second hands 110 and 120 may move together in the first direction D1. Specifically, the first hand 110 is connected to the first actuator 130 or the second actuator 140, the second hand 120 is connected to the first actuator 130, and the first actuator 130 penetrates the second hand 120 and is connected to the second actuator 140. Accordingly, as the second actuator 140 is driven in the first direction D1, the first hand 110, the second hand 120, and the first actuator 130 may move together in the first direction D1.

Referring to FIGS. 4-6 and FIG. 10, the second actuator 140 includes a slider 142, a motor 145, and a moving member 148.

The slider 142 is installed in the base 105. The slider 142 may move in the first direction D1 within the base 105. For example, a guide rail 143 may be installed within the base 105. The guide rail 143 extends in the first direction D1. The slider 142 is connected to the guide rail 143. The slider 142 may move in the first direction D1 along the guide rail 143.

The motor 145 provides power to the slider 142. The motor 145 moves the slider 142 in the first direction D1. For example, a plurality of pulleys 146a and 146b and a belt 147 may be installed within the base 105. The pulleys 146a and 146b are spaced apart from each other. The belt 147 connects the pulleys 146a and 146b. The pulley 146a may be connected to the motor 145 and may be rotated by the motor 145. The pulley 146a may rotate the belt 147. The slider 142 is connected to the belt 147. The slider 142 may move in the first direction D1 by receiving power of the motor 145 via the pulley 146a and the belt 147.

The moving member 148 is installed on the base 105. The moving member 148 is connected to the slider 142. The moving member 148 is fixed to the slider 142. The moving member 148 may move in the first direction D1 together with the slider 142. The first actuator 130 is fixed to the moving member 148. The first actuator 130 is fixed to the upper surface of the moving member 148 opposite to the bottom surface of the moving member 148 to which the slider 142 is connected. In some embodiments, when the first actuator 130 moves the first hand 110, the second hand 120 may be fixed to the moving member 148 of the second actuator 140.

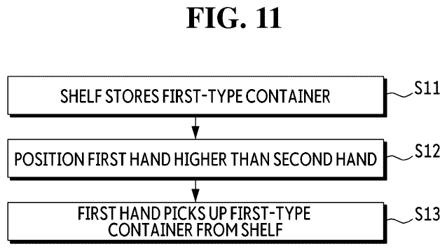

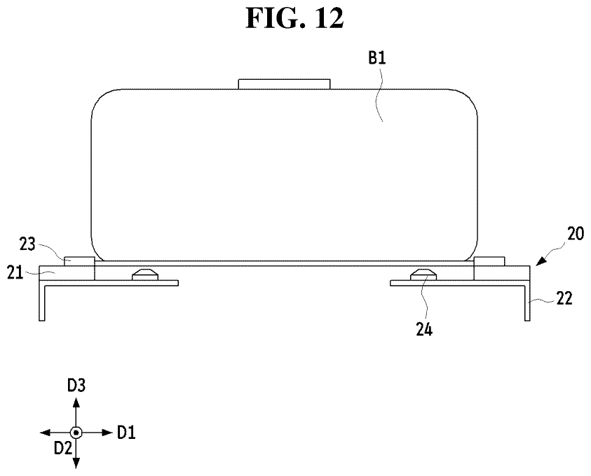

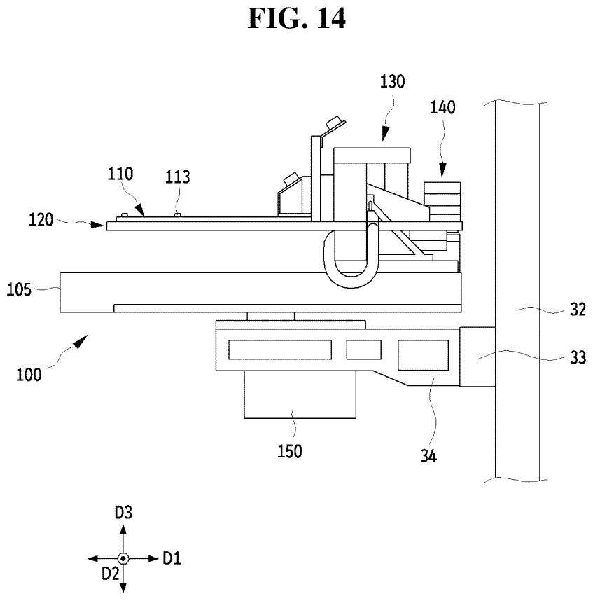

FIG. 11 is a flowchart for explaining an operation in which a transfer robot according to some embodiments of the present disclosure picks up a first-type container from a shelf. FIGS. 12-15 are intermediate drawings for explaining the operation of FIG. 11. For convenience of explanation, content overlapping with the description using FIGS. 1-10 will be briefly described or omitted.

Referring to FIGS. 11 and 12, a shelf 20 stores a first-type container B1 (S11).

The first-type container B1 is stored on the shelf 20. A first support 21 supports the first-type container B1. A plurality of fixing blocks 23 fix the first-type container B1.

Referring to FIGS. 11, 13, and 14, the first hand 110 is positioned higher than the second hand 120 (S12).

First, the transfer robot 100 moves to the shelf 20 storing the first-type container B1 through the moving device 31 and/or the elevator 33. Then, the controller 190 controls the first actuator 130 so that the first hand 110 is positioned higher than the second hand 120 relative to the base 105. The first actuator 130 moves at least one of the first and second hands 110 and 120 in the third direction D3 so as to position the first hand 110 higher than the second hand 120.

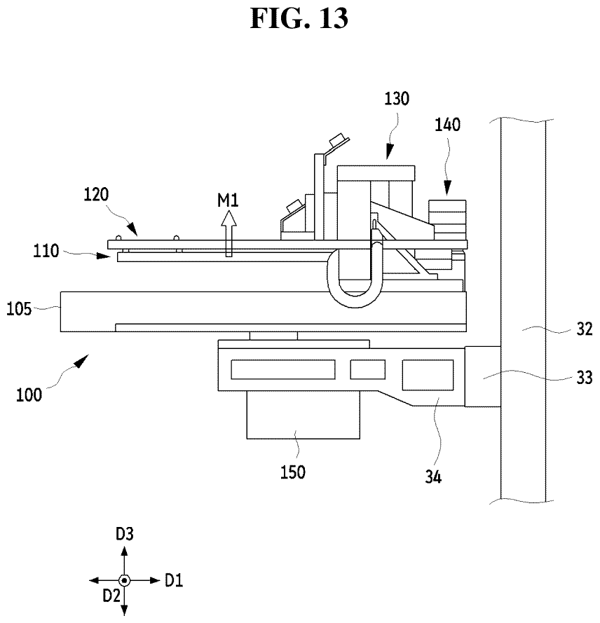

In some embodiments, the first actuator 130 moves the first hand 110 upward, as indicated by “M1” in FIG. 13, to position the first hand 110 higher than the second hand 120. In some embodiments, the first actuator 130 moves the second hand 120 downward, for example, in a direction opposite to M1, to position the first hand 110 higher than the second hand 120.

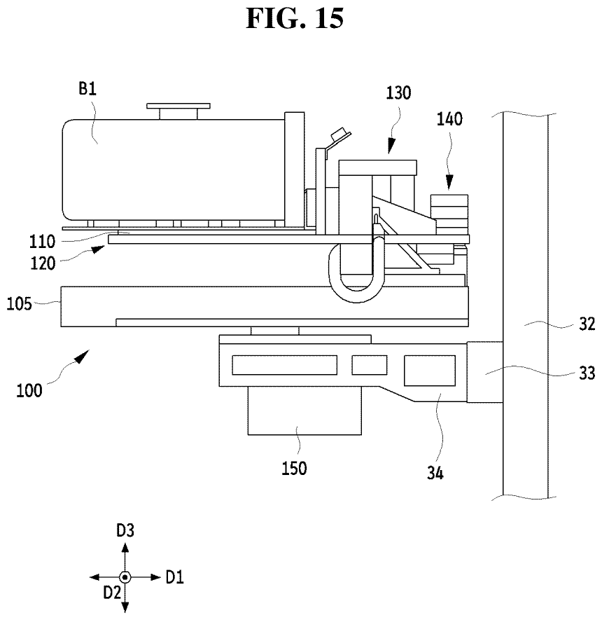

Referring to FIGS. 11 and 15, the first hand 110 picks up the first-type container B1 from the shelf 20 (S13).

First, the base 105 may perform a turning operation by the rotation actuator 150. The first and second hands 110 and 120 may perform the turning operation together with the base 105. When the base 105 performs the turning operation, the front-and-rear direction may change from the first direction D1 to the second direction D2. Hereinafter, a case where the base 105 performs the turning operation so that the front-and-rear direction is switched to the second direction D2 will be described.

In some embodiments, the order between the step of performing the turning operation of the first and second hands 110 and 120 and the step of adjusting the height between the first and second hands 110 and 120 may be changed. That is, after the first and second hands 110 and 120 perform the turning operation, the height between the first and second hands 110 and 120 may be adjusted.

Then, the first hand 110 picks up the first-type container B1 from the shelf 20. Specifically, the first hand 110 advances in the second direction D2 toward the shelf 20 by the second actuator 140. The second hand 120 advances together with the first hand 110 in the second direction D2 toward the shelf 20. The first hand 110 may enter beneath the first-type container B1 stored on the shelf 20. Then, the first hand 110 lifts the first-type container B1 from the shelf 20. The position pins 113 of the first hand 110 engage with holes formed in the bottom plate of the first-type container B1. Then, the first hand 110 retreats in the second direction D2 toward the base 105 by the second actuator 140.

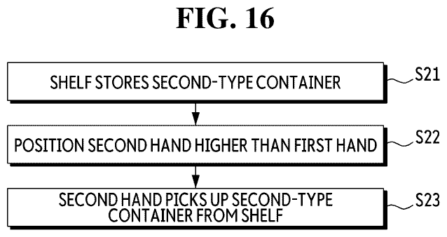

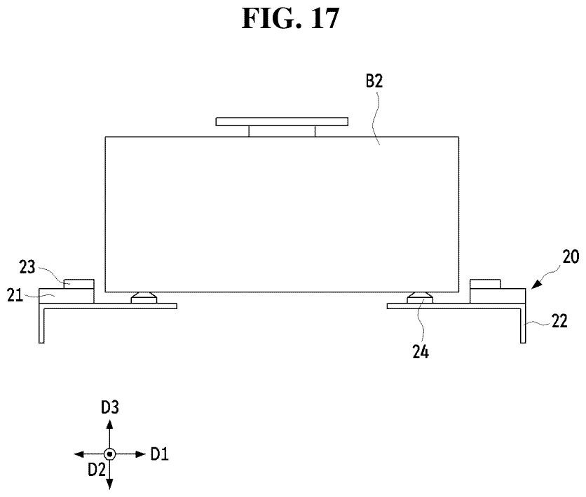

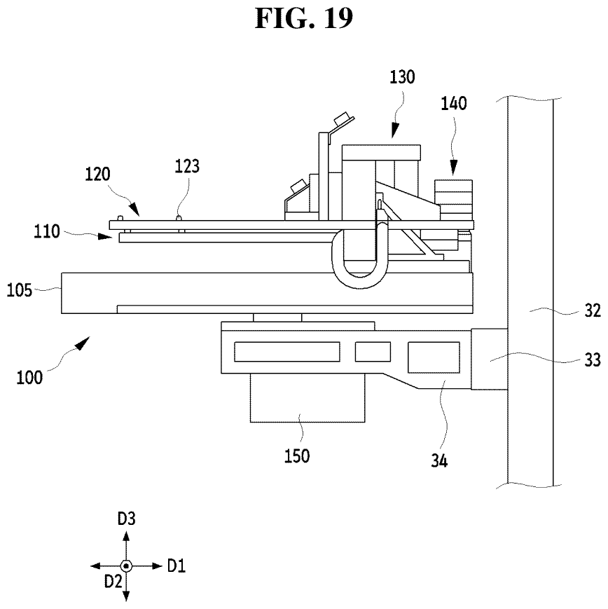

FIG. 16 is a flowchart for explaining an operation in which the transfer robot according to some embodiments of the present disclosure picks up a second-type container from a shelf. FIGS. 17-20 are intermediate drawings for explaining the operation of FIG. 16. For convenience of explanation, content overlapping with the description using FIGS. 1-15 will be briefly described or omitted.

Referring to FIGS. 16 and 17, the shelf stores a second-type container (S21).

The second-type container B2 is stored on the shelf 20. The second support 22 supports the second-type container B2. A plurality of support blocks 24 fix the second-type container B2.

Referring to FIGS. 16, 18, and 19, the second hand is positioned higher than the first hand (S22).

First, the transfer robot 100 moves to the shelf 20 storing the second-type container B2 through the moving device 31 and/or the elevator 33. Then, the controller 190 controls the first actuator 130 so that the second hand 120 is positioned higher than the first hand 110 relative to the base 105. The first actuator 130 moves at least one of the first hand 110 and the second hand 120 in the third direction D3 so as to position the second hand 120 higher than the first hand 110.

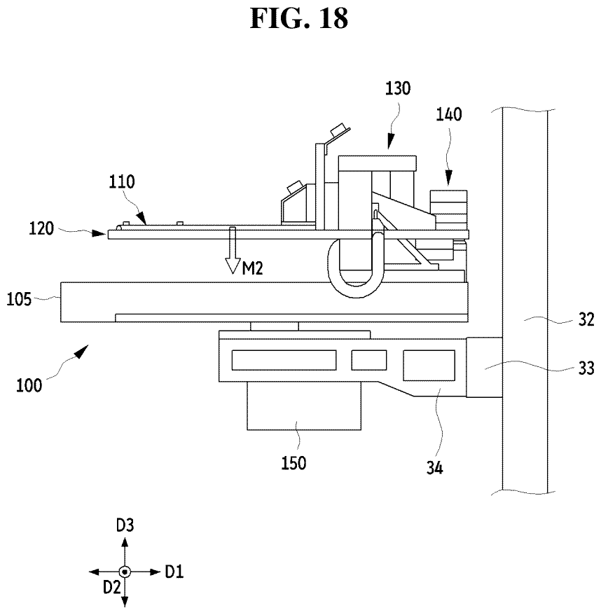

In some embodiments, the first actuator 130 moves the first hand 110 downward (see M2 of FIG. 18) to position the first hand 110 lower than the second hand 120. In some embodiments, the first actuator 130 moves the second hand 120 upward (for example, in a direction opposite to M2) to position the second hand 120 higher than the first hand 110.

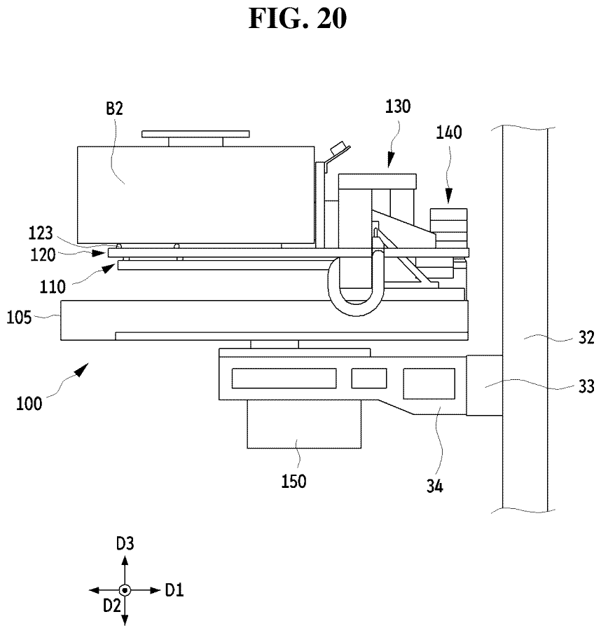

Referring to FIGS. 16 and 20, the second hand picks up the second-type container from the shelf (S23).

First, the first hand 110 and the second hand 120 may perform a turning operation together with the base 105. When the base 105 performs the turning operation, the front-and-rear direction may change from the front-and-rear direction D1 to the second direction D2. Hereinafter, a case where the base 105 performs the turning operation and the front-and-rear direction is the second direction D2 will be described as a reference.

In some embodiments, the order between the step of performing the turning operation of the first hand 110 and the second hand 120 and the step of adjusting a height between the first hand 110 and the second hand 120 may be changed.

Then, the second hand 120 picks up the second-type container B2 from the shelf 20. Specifically, the second hand 120 advances in the second direction D2 toward the shelf 20 by the second actuator 140. Then, the second hand 120 lifts the second-type container B2 from the shelf 20. The support blocks 123 of the second hand 120 contact the bottom plate of the second-type container B2 to support the second-type container B2. Then, the second hand 120 retreats in the second direction D2 toward the base 105 via the second actuator 140.

In summary, the transfer robot 100 of the container storage facility 1 includes the first hand 110, which can pick up a first-type container B1, the second hand 120, which can pick up a second-type container B2 having a size different from that of the first-type container B1, and the first actuator 130, which can adjust the height between the first and second hands 110 and 120. The transfer robot 100 may adjust the height between the first and second hands 110 and 120 depending on whether a target container to be picked up is the first-type container B1 or the second-type container B2. In addition, each of the shelves 20 of the container storage facility 1 includes a first support 21 that supports the first-type container B1 and a second support 22 that supports the second-type container B2. Since the shelves 20 can store different types of containers (B1 and B2) and the crane 30 including the transfer robot 100 can transfer different types of containers (B1 and B2), a container storage facility 1 capable of storing and transferring different types of containers (B1 and B2) may be provided.

Although embodiments of the present disclosure have been described, the present disclosure is not limited to the above embodiments and may be implemented in various different forms, and one of ordinary skill in the art to which the present disclosure pertains will understand that the present disclosure may be embodied in other specific forms without changing the technical spirit or essential features of the present disclosure. Therefore, the embodiments described above are to be understood as illustrative in all respects and not restrictive.

What is claimed is:

1. A transfer robot comprising:
a base;
a first hand installed on the base and configured to pick up a first-type container having a first width;
a second hand installed on the base and configured to pick up a second-type container having a second width different from the first width, the second hand including a passage through which the first hand passes;
a first actuator configured to adjust a position in an up-and-down direction between the first hand and the second hand; and
a controller configured to control the first actuator,
wherein, in a case where the first hand picks up the first-type container, the controller controls the first actuator to position the first hand higher than the second hand relative to the base.

2. The transfer robot of claim 1, wherein, in a case where the second hand picks up the second-type container, the controller controls the first actuator to position the second hand higher than the first hand relative to the base.

3. The transfer robot of claim 1, further comprising:
a second actuator installed on the base and configured to move the first hand and the second hand in a front-and-rear direction,
wherein the first actuator is connected to the second actuator by penetrating the second hand.

4. The transfer robot of claim 3, wherein
the first actuator comprises: a frame that penetrates the second hand and is connected to the second actuator; and a moving member installed on the frame and moving in the up-and-down direction,
the first hand is fixed to the moving member, and
the second hand is fixed to the frame.

5. The transfer robot of claim 3, wherein
the first actuator comprises: a frame that penetrates the second hand and is connected to the second actuator; and a moving member installed on the frame and moving in the up-and-down direction,
the second hand is fixed to the moving member, and
the first hand is fixed to the frame.

6. The transfer robot of claim 1, wherein
the first width is greater than the second width, and
a width of the first hand is smaller than a width of the second hand.

7. The transfer robot of claim 1, wherein the first actuator comprises: a frame that penetrates the second hand; a ball screw installed on the frame and extending in the up-and-down direction; and a moving member including a front surface to which the first hand is fixed and a rear surface opposite to the front surface and connected to the ball screw.

8. The transfer robot of claim 1, wherein
the first hand includes a plurality of position pins that engage a plurality of holes formed in a bottom plate of the first-type container, and
the second hand includes a plurality of support blocks that contact a bottom plate of the second-type container to support the second-type container.

9. The transfer robot of claim 1, further comprising:
a rotation actuator installed below the base and configured to rotate the base.

10. The transfer robot of claim 1, wherein
the first-type container is a Front Opening Unified Pod (FOUP) or a Front Opening Shipping Box (FOSB), and
the second-type container is a cassette.

11. A container storage facility comprising:
a shelf configured to selectively store a first-type container having a first width or a second-type container having a second width, different from the first width; and
a crane configured to transfer the first-type container and the second-type container to the shelf and comprising a body and a transfer robot configured to move up and down relative to the body;
wherein the transfer robot comprises: a base; a first hand installed on the base and configured to pick up the first-type container from the shelf; a second hand installed on the base and configured to pick up the second-type container from the shelf, the second hand including a passage through which the first hand passes; and a first actuator configured to adjust a position in an up-and-down direction between the first hand and the second hand.

12. The container storage facility of claim 11, wherein the shelf comprises: a first support configured to support the first-type container; and a second support installed below the first support and configured to support the second-type container.

13. The container storage facility of claim 12, wherein
the first support includes a first portion and a second portion spaced apart from each other,
the second support includes a third portion and a fourth portion spaced apart from each other,
the first portion is connected to the third portion, and
the second portion is connected to the fourth portion.

14. The container storage facility of claim 11, wherein
the transfer robot further comprises a controller configured to control the first actuator, and
wherein, in a case where the transfer robot picks up the first-type container stored on the shelf, the controller controls the first actuator to position the first hand higher than the second hand relative to the base.

15. The container storage facility of claim 14, wherein, in a case where the transfer robot picks up the second-type container, the controller controls the first actuator to position the second hand higher than the first hand relative to the base.

16. The container storage facility of claim 11, wherein
the transfer robot further comprises a second actuator installed on the base and configured to move the first hand and the second hand in a front-and-rear direction, and
the first actuator penetrates the second hand and is connected to the second actuator.

17. The container storage facility of claim 16, wherein
the first actuator comprises: a frame that penetrates the second hand and is connected to the second actuator; and a moving member installed on the frame and moving in the up-and-down direction,
the first hand is fixed to the moving member, and
the second hand is fixed to the frame.

18. The container storage facility of claim 16, wherein
the first actuator comprises: a frame that penetrates the second hand and is connected to the second actuator; and a moving member installed on the frame and moving in the up-and-down direction,
the second hand is fixed to the moving member, and
the first hand is fixed to the frame.

19. The container storage facility of claim 11, wherein
the first width is greater than the second width, and
a width of the first hand is smaller than a width of the second hand.

20. A container storage facility comprising:
a shelf configured to selectively store a first-type container having a first width or a second-type container having a second width, smaller than the first width, the shelf comprising a first support configured to support the first-type container and a second support installed below the first support and configured to support the second-type container; and
a crane configured to transfer the first-type container and the second-type container to the shelf, and comprising a body and a transfer robot configured to move up and down relative to the body,
wherein
the transfer robot comprises: a base; a first hand installed on the base and configured to pick up the first-type container from the shelf; a second hand installed on the base and configured to pick up the second-type container from the shelf, the second hand including a passage through which the first hand passes; an actuator connected to the first hand and penetrating the second hand, the actuator being configured to move the first hand in the up-and-down direction relative to the base; and a controller configured to control the actuator,
in a case where the first hand picks up the first-type container, the controller controls the actuator to position the first hand higher than the second hand relative to the base, and
in a case where the second hand picks up the second-type container, the controller controls the actuator to position the first hand lower than the second hand relative to the base.
